(19) United States
(12) Patent Application Publication
(10) Pub. No.: US 2022/0018723 A1
(43) Pub. Date: Jan. 20, 2022

(54) TORQUE DETECTION SENSOR

(71) Applicant: SHINANO KENSHI KABUSHIKI KAISHA, Nagano (JP)

(72) Inventor: Akihide FURUKAWA, Nagano (JP)

(21) Appl. No.: 17/340,248

(22) Filed: Jun. 7, 2021

(30) Foreign Application Priority Data
Jul. 17, 2020 (JP) 2020-122674

(51) Int. Cl. G01L 3/10; H01L 41/12

(52) U.S. Cl. CPC G01L 3/102; H01L 41/125

(57) ABSTRACT

A first torque detection part and a second torque detection part are stacked so that a first energizing circuit and a third energizing circuit as well as a second energizing circuit and a fourth energizing circuit are arranged in mirror symmetry with respect to a symmetry plane orthogonal to an axial center direction of an object to be detected, and a plurality of magnetic paths are respectively formed between teeth having inclinations of ±45 degrees in the first torque detection part and the second torque detection part.

### CROSS-REFERENCE TO RELATED APPLICATION

This application is based upon and claims the benefit of priority of the prior Japanese Patent Application No. 2020-122674, filed on Jul. 17, 2020, and the entire contents of which are incorporated herein by reference.

### TECHNICAL FIELD

The present invention relates to a self-excitation torque detection sensor.

### BACKGROUND ART

There exists a magnetostrictive torque detection device as a method for detecting torque acting on an object to be detected such as a rotary shaft by a non-contact manner. For example, surface treatment (for example, plating, grooving, or the like) for increasing magnetostrictive characteristics is performed on the surface of a shaft to be detected distortion of which is detected, and magnetostrictive effect is measured to detect the torque. The measurement of the magnetostrictive effect is executed by arranging coils coaxially wound around the shaft and reading variation in magnetic permeability of the shaft generated by Villari effect based on the magnitude of impedance.

As the torque detection device, the applicants have proposed a magnetostrictive torque detection sensor in which magnetic paths formed between the object to be detected and a plurality of cores assembled to insulation cylindrical bodies so that the magnetic paths formed at the object to be detected have a prescribed angle with respect to its axis center are respectively increased to thereby improve torque detection sensitivity. The plural cores are disposed in an inclined manner at a prescribed angle with respect to an axial center direction of the object to be detected so that end faces of both side leg portions face the object to be detected from inner circumferential surfaces of the insulation cylindrical bodies. As the cores formed in a U-shape are disposed in the inclined manner at the prescribed angle with respect to the axial center of the object to be detected, an independent magnetic path passing one leg portion (end surface), the object to be detected, the other leg portion (end surface), and a bridge portion is formed. As described above, the same magnetic field is generated around a coil as the same coil passes through the plural cores, which forms the same pole.

Accordingly, magnetic fluxes are concentrated to the cores and a magnetic path connecting adjacent cores to each other is not easily formed; therefore, a structure in which detection sensitivity is improved can be obtained (PTL 1: Japanese Patent No. 6483778).

### SUMMARY OF INVENTION

### Technical Problem

However, in the torque detection device of the above patent literature, it is necessary to form grooves on an outer peripheral surface of the insulation cylindrical bodies and to wind a plural detection coils along the grooves, and further, the plural cores are assembled to the insulation cylindrical bodies so that the detection coils pass through a U-shaped space surrounded by the bridge portion connecting the both side leg portions.

Accordingly, it is necessary to embed the detection coils and the cores by utilizing the thickness of the insulation cylindrical bodies in a radial direction; therefore, the sensor tends to be increased in size in the radial direction and an axial direction. As the end faces of both side leg portions forming the cores are provided so as to face the object to be detected, the shape of the end faces has to be, not a flat surface, but an arc-shaped curved surface, which increases processing costs.

There is also a demand that torque is delicately detected over the entire periphery of the object to be detected by increasing magnetic paths effective for torque detection.

### Solution to Problem

In response to the above issue, one or more aspects of the present invention are directed to a self-excitation torque detection sensor capable of reducing the size of the sensor and being mass produced at low cost as well as capable of delicately detecting compressive stress and tensile stress generated over the entire periphery of an object to be detected by increasing magnetic path effective for torque detection.

In view of the above, the following embodiments are described below. A torque detection sensor measures variation of magnetic permeability by variation of coil impedance in magnetic circuits formed between a core and an object to be detected by energizing coils wound around teeth provided to protrude from the annular core provided around the object to be detected at plural places, which includes a first torque detection part in which a plurality of first teeth and second teeth are provided to protrude in staggered arrangement in annular first and second cores in a circumferential direction, having a first energizing circuit in which first coils wound around the first teeth and second coils wound around the second teeth arranged with an inclination of +45 degrees with respect to an axial center direction of the object to be detected are connected in series, and a second energizing circuit in which the first coils wound around the first teeth and the second coils wound around the second teeth arranged with an inclination of −45 degrees with respect to the axial center direction of the object to be detected are connected in series, and a second torque detection part in which a plurality of third teeth and fourth teeth are provided to protrude in staggered arrangement in annular third and fourth cores in a circumferential direction, having a third energizing circuit in which third coils wound around the third teeth and fourth coils wound around the fourth teeth arranged with the inclination of +45 degrees with respect to the axial center direction of the object to be detected are connected in series, and a fourth energizing circuit in which the third coils wound around the third teeth and the fourth coils wound around the fourth teeth arranged with the inclination of −45 degrees with respect to the axial center direction of the object to be detected are connected in series, in which the first torque detection part and the second torque detection part are stacked so that the first energizing circuit and the third energizing circuit are arranged in mirror symmetry as well as the second energizing circuit and the fourth energizing circuit are arranged in mirror symmetry with respect to a symmetry plane orthogonal to the axial center direction of the object to be detected.

According to the above configuration, when the first torque detection part and the second torque detection part are stacked so that the first energizing circuit and the third energizing circuit are arranged in mirror symmetry as well as the second energizing circuit and the fourth energizing circuit are arranged in mirror symmetry with respect to the symmetry plane orthogonal to the axial center direction of the object to be detected, a plurality of magnetic paths are respectively formed between the teeth having inclinations of ±45 degrees in the first torque detection part and the second torque detection part; therefore, compressive stress and tensile stress generated over the entire periphery of the object to be detected can be delicately detected by increasing magnetic paths effective for torque detection.

Arrangement of magnetic poles of the first teeth and the second teeth excited by the first energizing circuit and the second energizing circuit and arrangement of magnetic poles of the third teeth and the fourth teeth excited by the third energizing circuit and the fourth energizing circuit may be in mirror symmetry through the symmetry plane.

According to the above, a large number of magnetic paths effective for torque detection having inclinations of ±45 degrees are formed between the teeth provided in staggered arrangement to thereby improve detection sensitivity.

The first teeth adjacent to each other in the circumferential direction of the first core, the second teeth adjacent to each other in the circumferential direction of the second core, the third teeth adjacent to each other in the circumferential direction of the third core, and the fourth teeth adjacent to each other in the circumferential direction of the fourth core may be excited to the same polarity.

In this case, magnetic paths are not formed between teeth so as to cross the symmetry plane between the first torque detection part and the second torque detection part, which can improve detection sensitivity.

The first teeth of the first core and the third teeth of the third core arranged at symmetrical positions through the symmetry plane as well as the second teeth of the second core and the fourth teeth of the fourth core arranged at symmetrical positions through the symmetry plane in the first torque detection part and the second torque detection part may be excited to the same polarity.

In this case, magnetic paths are not formed between teeth so as to cross the symmetry plane between the first torque detection part and the second torque detection part; however, magnetic paths are formed between teeth adjacent in the circumferential direction in the first teeth and the fourth teeth. However, these magnetic paths have magnetic path components having little effect on torque detection, which have little effect on detection sensitivity.

The first teeth of the first core and the third teeth of the third core arranged at symmetrical positions through the symmetry plane as well as the second teeth of the second core and the fourth teeth of the fourth core arranged at symmetrical positions through the symmetry plane in the first torque detection part and the second torque detection part may be excited to different polarities.

In this case, magnetic paths are formed between teeth adjacent in the circumferential direction in the first teeth and the third teeth, and further, magnetic paths are formed in the axial center direction of the object to be detected between the second teeth and the fourth teeth so as to cross the symmetry plane between the first torque detection part and the second torque detection part. However, these magnetic path components have little effect on torque detection, which have little effect on detection sensitivity.

A torque detection sensor measures variation of magnetic permeability by variation of coil impedance in magnetic circuits formed between a core and an object to be detected by energizing coils wound around teeth provided to protrude from the annular core provided around the object to be detected at plural places, which includes a first torque detection part in which a plurality of first teeth and second teeth are provided to protrude in staggered arrangement in annular first and second cores in a circumferential direction, having a first energizing circuit in which first coils wound around the first teeth and second coils wound around the second teeth arranged with an inclination of +45 degrees with respect to an axial center direction of the object to be detected are connected in series, and a second energizing circuit in which the first coils wound around the first teeth and the second coils wound around the second teeth arranged with an inclination of −45 degrees with respect to the axial center direction of the object to be detected are connected in series, and a second torque detection part in which a plurality of third teeth and fourth teeth are provided to protrude in staggered arrangement in annular third and fourth cores in a circumferential direction, having a third energizing circuit in which third coils wound around the third teeth and fourth coils wound around the fourth teeth arranged with the inclination of +45 degrees with respect to the axial center direction of the object to be detected are connected in series, and a fourth energizing circuit in which the third coils wound around the third teeth and the fourth coils wound around the fourth teeth arranged with the inclination of −45 degrees with respect to the axial center direction of the object to be detected are connected in series, in which the first torque detection part and the second torque detection part are stacked so that layouts are the same between the first energizing circuit and the third energizing circuit, and layouts are the same between the second energizing circuit and the fourth energizing circuit in the axial center direction and a circumferential direction of the object to be detected.

In this case, layouts are the same between the first energizing circuit and the third energizing circuit, and layouts are the same between the second energizing circuit and the fourth energizing circuit in the axial center direction and the circumferential direction of the object to be detected in the first torque detection part and the second torque detection part; therefore, a large number of plural magnetic paths having inclinations of ±45 degrees are formed along an axial direction, for example, only by preparing a plurality of first torque detection parts and stacking them in the axial center direction of the object to the detected. Accordingly, compressive stress and tensile stress generated over the entire periphery of the object to be detected can be delicately detected by increasing magnetic paths effective for torque detection.

It is preferable that teeth are stacked so that magnetic poles of the first teeth and the second teeth excited by the first energizing circuit and the second energizing circuit are asymmetrically arranged with respect to magnetic poles of the third teeth and the fourth teeth excited by the third energizing circuit and the fourth energizing circuit. Accordingly, it is possible to manufacture the toque detection sensor having high detection sensitivity, for example, only by creating a plurality of first torque detection parts and stacking them so as to align layouts of the energizing circuits in the axial center direction and the circumferential direction.

The first teeth adjacent to each other in the circumferential direction of the first core, the second teeth adjacent to each other in the circumferential direction of the second core, the third teeth adjacent to each other in the circumferential direction of the third core, and the fourth teeth adjacent to each other in the circumferential direction of the fourth core may be excited to the same polarity.

In this case, magnetic paths generated from the first teeth to the second teeth having a phase difference of 45 degrees and magnetic paths generated from the first teeth to the third teeth so as to cross a lamination plane in the axial center direction are formed.

Moreover, magnetic paths generated from the fourth teeth to the third teeth having the phase difference of 45 degrees and magnetic paths generated from the fourth teeth to the second teeth so as to cross the lamination plane in the axial center direction are formed.

The magnetic paths generated from the first teeth to the third teeth so as to cross the lamination plane in the axial center direction and the magnetic paths generated from the fourth teeth to the second teeth so as to cross the lamination plane in the axial center direction have magnetic path components having little effect on torque detection, which have little effect on detection sensitivity. Accordingly, plural magnetic paths having inclinations of ±45 degrees are respectively formed along the axial direction; therefore, torque can be detected though the efficiency is reduced.

The first teeth adjacent to each other in the circumferential direction of the first core, the second teeth adjacent to each other in the circumferential direction of the second core, the third teeth adjacent to each other in the circumferential direction of the third core, and the fourth teeth adjacent to each other in the circumferential direction of the fourth core may be excited to different polarities.

In this case, magnetic paths generated from the first teeth to the second teeth having the phase difference of 45 degrees, magnetic paths directed to teeth adjacent in the circumferential direction of the first teeth, and magnetic paths generated from the first teeth to the third teeth so as to cross the lamination plane in the axial center direction are formed.

Moreover, magnetic paths directed to teeth adjacent in the circumferential direction of the second teeth, magnetic paths generated from the second teeth to the first teeth having the phase difference of 45 degrees, and magnetic paths generated from the second teeth to the fourth teeth so as to cross the lamination plane in the axial center direction are formed.

Magnetic paths directed to teeth adjacent in the circumferential direction of the third teeth, magnetic paths generated from the third teeth to the second teeth having the phase difference of 45 degrees, magnetic paths generated from the third teeth to the first teeth so as to cross the lamination plane in the axial center direction, and magnetic paths generated from the third teeth to the fourth teeth having the phase difference of 45 degrees are respectively formed.

Furthermore, magnetic paths generated from the fourth teeth to the third teeth having the phase difference of 45 degrees, magnetic paths directed to teeth adjacent in the circumferential direction of the fourth teeth, and magnetic paths generated from the fourth teeth to the second teeth so as to cross the lamination plane in the axial center direction are formed.

The above magnetic paths formed from the first to the fourth teeth so as to cross the lamination plane in the axial center direction and the magnetic paths generated from respective teeth to adjacent teeth in the circumferential direction have magnetic path components having little effect on torque detection, which have little effect on detection sensitivity. Accordingly, plural magnetic paths having inclinations of ±45 degrees are respectively formed along the axial direction; therefore, torque can be detected though the efficiency is reduced.

The sensor may be a self-excitation sensor measuring variation of magnetic permeability by variation of coil impedance in magnetic circuits formed between the core and the object to be detected by supplying power to the first energizing circuit, the second energizing circuit, the third energizing circuit, and the fourth energizing circuit.

In this case, a plurality of magnetic paths having the inclination of +45 degrees and a plurality of magnetic paths having the inclination of −45 degrees with respect to the axial center direction of the object to be detected are formed between the core and the object to be detected by supplying power to the first energizing circuit to the fourth energizing circuit at arbitrary timing, thereby detecting compressive stress and tensile stress acting on the object to be detected.

### Advantageous Effects of Invention

The sensor can be reduced in size and mass-produced at low cost, and further, compressive stress and tensile stress generated over the entire periphery of the object to be detected can be delicately detected by increasing magnetic paths effective for torque detection.

### BRIEF DESCRIPTION OF DRAWINGS

FIGS. 1A to 1D are a front view, a right-side view, a cross-sectional view taken along an arrow Y-Y direction, and a perspective view of a torque detection sensor.

FIG. 2 is a developed view showing a stacked state of cores and an explanatory view for energizing circuits according to Embodiment 1.

FIG. 3 is an explanatory view for magnetic paths formed between teeth when supplying power to the energizing circuits of FIG. 2.

FIG. 4 is an explanatory view for magnetic paths formed between teeth when supplying power to energizing circuits according to Embodiment 2.

FIG. 5 is an explanatory view for magnetic paths formed between teeth when supplying power to energizing circuits according to Embodiment 3.

FIG. 6 is a developed view showing a stacked state of cores and an explanatory view for energizing circuits according to Embodiment 4.

FIG. 7 is an explanatory view for magnetic paths formed between teeth when supplying power to the energizing circuits of FIG. 6.

FIG. 8 is an explanatory view for magnetic paths formed between teeth when supplying power to the energizing circuits of FIG. 6 according to Embodiment 5.

FIG. 9 is a developed view of cores and an explanatory view for energizing circuits of a torque detection sensor according to another example.

FIG. 10 is an explanatory view for magnetic paths formed between teeth when supplying power to the energizing circuits of FIG. 9 according to Embodiment 6.

FIG. 11 is a developed view of cores and an explanatory view for energizing circuits of a torque detection sensor according to another example.

FIG. 12 is an explanatory view for magnetic paths formed between teeth when supplying power to the energizing circuits of FIG. 11 according to Embodiment 7.

FIG. 13 is an explanatory view for magnetic paths formed between teeth relating to a comparative example of FIG. 10.

FIG. 14 is an explanatory view for magnetic paths formed between teeth relating to a comparative example of FIG. 12.

FIGS. 15A to 15C are a front view, a right-side view, and a perspective view of a torque detection sensor and an object to be detected according to another example.

### DESCRIPTION OF EMBODIMENTS

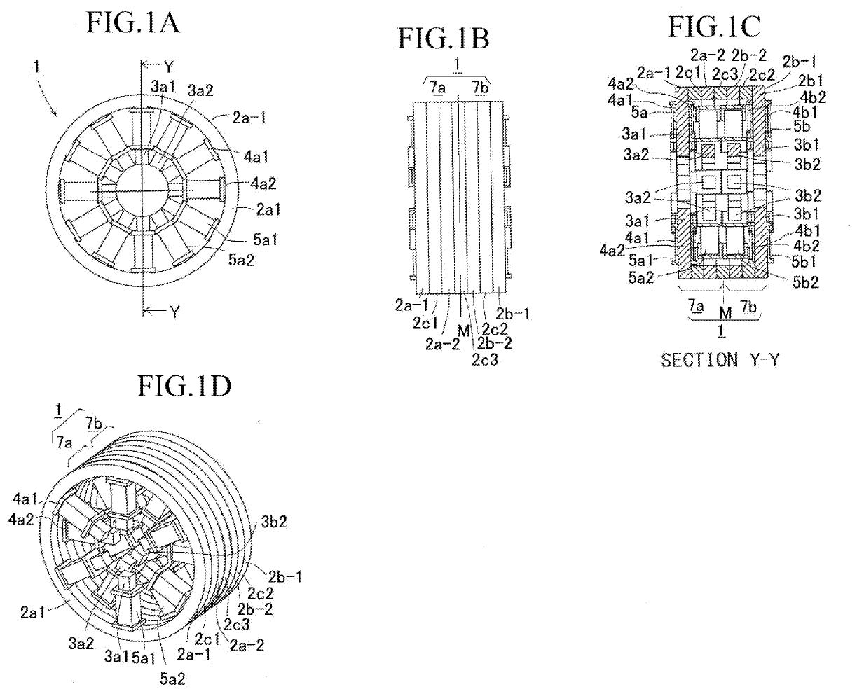

Hereinafter, a torque detection sensor according to an embodiment of the present invention will be explained with reference to the attached drawings. First, a schematic configuration of a torque detection sensor 1 will be explained with reference to FIGS. 1A to 1D to FIG. 14.

As an example of an object to be detected, a material with high inverse magnetostrictive effect is preferable. For example, there are permendur, Fe—Al (ALFE), Fe-Nix (permalloy), spherical graphite cast iron (JIS: FCD70), and the like as materials with high inverse magnetostrictive effect. The inverse magnetostrictive effect is a phenomenon in which magnetic characteristics are changed when stress is added to a magnetic body from the outside. When magnetic annealing is previously performed to the object to be detected according to need, the torque acting on the object to be detected can be suitably detected, which will be described in detail later. Even in a non-magnetic material, the torque can be detected by coating the material with a metal magnetic material by performing thermal spraying or by press-fitting a magnetic cylinder into a shaft. The object to be detected has a columnar shape, but the shape is not limited to this. An internal structure does not matter as long as the object to be detected has the columnar outer shape. For example, a cylindrical shape in which an inner diameter is fixed in an axial direction or a cylindrical shape in which the inner diameter differs according to positions in the axial direction may be adopted. Moreover, the object to be detected may be an object expected to rotate as well as an object not expected to rotate. Furthermore, the object to be detected may be a solid shaft material as well as a hollow shaft or the like.

The torque detection sensor 1 measures variation of magnetic permeability by variation of coil impedance in magnetic circuits formed between teeth and the object to be detected by energizing coils wound around the teeth provided to protrude from an annular core provided around the object to the detected at plural places.

In FIG. 1C, a first torque detection part 7a is formed so that a plurality of first teeth 3a1 and second teeth 3a2 are provided to protrude in an annular first core 2a-1 and an annular second core 2a-2 in a circumferential direction toward an inner side in a radial direction. The first core 2a-1 and the second core 2a-2 are stacked on each other through an intermediate core 2c1, thereby providing the first teeth 3a1 and the second teeth 3a2 in staggered arrangement. More precisely, tip portions of the first teeth 3a1 facing the object to be detected and tip portions of the second teeth 3a2 facing the object to be detected are stacked through the intermediated core 2c1 so as to have a phase difference of +45 degrees in the circumferential direction. First insulators 4a1, second insulators 4a2 are respectively fitted around the respective first teeth 3a1 and second teeth 3a2, and first coils 5a1 and second coils 5a2 are respectively wound therearound, which are connected to later-described first and second energizing circuits 6a1, 6a2. When the first coils 5a1 and the second coils 5a2 connected to the first and second energizing circuits 6a1, 6a2 are energized, the first teeth 3a1 and the second teeth 3a2 adjacent to each other are excited to different magnetic poles, and a plurality of magnetic paths having inclinations of ±45 degrees with respect to an axial center direction are formed between the teeth and the facing object to be detected. The first teeth 3a1 and the second teeth 3a2 are excited to different magnetic poles by inverting winding directions of the first coils 5a1 and the second coils 5a2 connected in series.

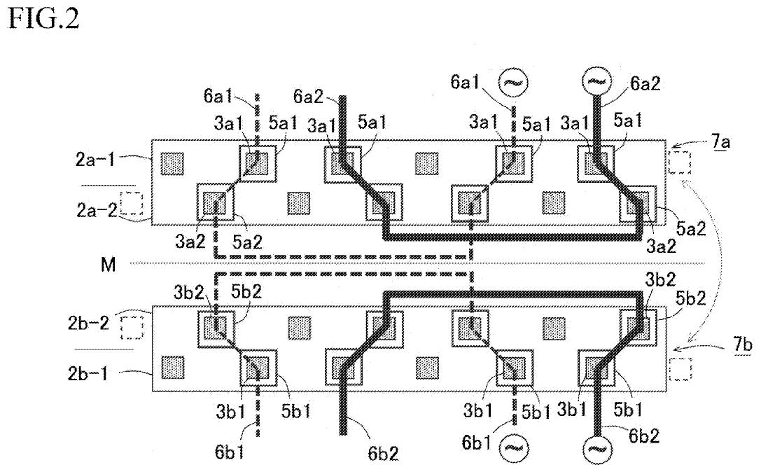

As shown in a developed view of the first core 2a-1 and the second core 2a-2 in FIG. 2, the first torque detection part 7a includes the first energizing circuit 6a1 (refer to a broken line) in which the first coils 5a1 and the second coils 5a2 respectively wound around the first teeth 3a1 and the second teeth 3a2 having an inclination of +45 degrees with respect to the axial center direction (a vertical direction in FIG. 2) of the object to the detected are connected in series, and the second energizing circuit 6a2 (refer to a solid line) in which the first coils 5a1 and the second coils 5a2 respectively wound around the first teeth 3a1 and the second teeth 3a2 having an inclination of −45 degrees with respect to the axial center direction (the vertical direction in FIG. 2) of the object to the detected are connected in series. The first energizing circuit 6a1 and the second energizing circuit 6a2 are arranged so as to cross each other.

In FIG. 1C, a second torque detection part 7b is formed so that a plurality of third teeth 3b1 and fourth teeth 3b2 are provided to protrude in an annular third core 2b-1 and an annular fourth core 2b-2 toward the inner side in the radial direction. The third core 2b-1 and the fourth core 2b-2 are stacked on each other through an intermediate core 2c2, thereby providing the third teeth 3b1 and the fourth teeth 3b2 in staggered arrangement. More precisely, tip portions of the third teeth 3b1 facing the object to be detected and tip portions of the fourth teeth 3b2 facing the object to be detected are stacked through the intermediated core 2c2 so as to have a phase difference of −45 degrees in the circumferential direction. Third insulators 4b1 and fourth insulators 4b2 are respectively fitted around the respective third teeth 3b1 and the fourth teeth 3b2, and third coils 5b1 and fourth coils 5b2 are respectively wound therearound, which are connected to later-described third and fourth energizing circuits 6b1, 6b2. When the third coils 5b1 and the fourth coils 5b2 connected in series to the third and fourth energizing circuits 6b1, 6b2 are energized, a plurality of magnetic paths having inclinations of ±45 degrees with respect to the axial center direction are formed between the teeth and the facing object to be detected. The third teeth 3b1 and the fourth teeth 3b2 are excited to different magnetic poles by inverting winding directions of the third coils 5b1 and the fourth coils 5b2 connected in series.

As shown in a developed view of the third core 2b-1 and the fourth core 2b-2 in FIG. 2, the second torque detection part 7b includes the third energizing circuit 6b1 (refer to a broken line) in which the third coils 5b1 and the fourth coils 5b2 respectively wound around the third teeth 3b1 and the fourth teeth 3b2 having an inclination of +45 degrees with respect to the axial center direction of the object to the detected are connected in series, and the fourth energizing circuit 6b2 (refer to a solid line) in which the third coils 5b1 and the fourth coils 5b2 respectively wound around the third teeth 3b1 and the fourth teeth 3b2 having an inclination of −45 degrees with respect to the axial center direction of the object to the detected are connected in series. The third energizing circuit 6b1 and the fourth energizing circuit 6b2 are arranged so as to cross each other. Phase differences between teeth may be the same as well as different from one another. The number of teeth may be an even number as well as an odd number.

The first torque detection part 7a and the second torque detection part 7b are stacked so that the first energizing circuit 6a1 and the third energizing circuit 6b1 are arranged in mirror symmetry with respect to a symmetry plane M orthogonal to the axial center direction of the object to be detected, and that the second energizing circuit 6a2 and the fourth energizing circuit 6b2 are arranged in mirror symmetry as shown in developed views of the first core 2a-1, the second core 2a-2, the third core 2b-1, and the fourth core 2b-2 in FIG. 2. The symmetry plane M is positioned at a central part of an intermediate core 2c3 in a stacked direction as shown in FIG. 1B.

As described above, plural magnetic paths are respectively formed between teeth with inclinations of ±45 degrees in the first torque detection part 7a and the second torque detection part 7b; therefore, compressive stress and tensile stress generated over the entire periphery of the object to be detected can be delicately detected by increasing the magnetic paths effective for torque detection.

As shown in the developed views of the first core 2a-1, the second core 2a-2, the third core 2b-1, and the fourth core 2b-2 in FIG. 2, magnetic poles of the first teeth 3a1 and the second teeth 3a2 excited by the first energizing circuit 6a1 and the second energizing circuit 6a2 and magnetic poles of the third teeth 3b1 and the fourth teeth 3b2 excited by the third energizing circuit 6b1 and the fourth energizing circuit 6b2 are arranged in mirror symmetry through the symmetry plane M. Accordingly, a large number of magnetic paths effective for torque detection having inclinations of ±45 degrees between the teeth provided in staggered arrangement are formed to thereby improve detection sensitivity.

In FIGS. 1A and 1D, the first teeth 3a1 provided to protrude in an annular core back portion 2a1 toward the inner side in the radial direction are provided with a phase difference of 60 degrees in the circumferential direction at six places in total in the first core 2a-1. The cylindrical first insulators 4a1 made of insulating resin are fitted to the respective first teeth 3a1 and the first coils Sal are wound therearound.

As shown in FIGS. 1B and 1C, the first core 2a-1 is stacked on the second core 2a-2 through the intermediate core 2c1. The second teeth 3a2 provided to protrude in the annular core back portion 2a1 toward the inner side in the radial direction are provided with the phase difference of 60 degrees in the circumferential direction at six places in total in the second core 2a-2. The cylindrical second insulators 4a2 made of insulating resin are fitted to the respective second teeth 3a2 and the second coils 5a2 are wound therearound. In the first core 2a-1 and the second core 2a-2, the first teeth 3a1 and the second teeth 3a2 are stacked so that phases are shifted by 45 degrees in the circumferential direction (see an upper stage of the core developed views in FIG. 2).

In FIG. 1C, the third teeth 3b1 provided to protrude in an annular core back portion 2b1 toward the inner side in the radial direction are provided with the phase difference of 60 degrees in the circumferential direction at six places in total in the third core 2b-1 in the same manner as the first core 2a-1. The cylindrical third insulators 4b1 made of insulating resin are fitted to the respective third teeth 3b1 and the third coils 5b1 are wound therearound.

As shown in FIG. 1C, the fourth core 2b-2 is stacked on the third core 2b-1 through the intermediate core 2c2. The fourth teeth 3b2 provided to protrude in the annular core back portion 2b1 toward the inner side in the radial direction are provided with the phase difference of 60 degrees in the circumferential direction at six places in total in the fourth core 2b-2. The cylindrical fourth insulators 4b2 made of insulating resin are fitted to the respective fourth teeth 3b2 and the fourth coils 5b2 are wound therearound. In the third core 2b-1 and the fourth core 2b-2, the third teeth 3b1 and the fourth teeth 3b2 are stacked so that phases are shifted by 45 degrees in the circumferential direction (see a lower stage of the core developed views in FIG. 2).

As shown in FIG. 1B, the cores are stacked so that the annular fourth core 2c3 is interposed between the second core 2a-2 and the fourth core 2b-2. The intermediate cores 2c1, 2c2, and 2c3 double as spacers for securing spaces where the first coils 5a1 and the second coils 5a2 are wound around the first teeth 3a1 and the second teeth 3a2, or the third coils 5b1 and the fourth coils 5b2 are wound around the third teeth 3b1 and the fourth teeth 3b2 between the first core 2a-1 and the second core 2a-2, between the third core 2b-1 and the fourth core 2b-2, or between the second core 2a-2 and the fourth core 2b-2, and magnetic paths generated between the first core 2a-1 and the second core 2a-2, between the third core 2b-1 and the fourth core 2b-2, or between the second core 2a-2 and the fourth core 2b-2. The intermediate cores 2c1, 2c2, and 2c3 are not provided with teeth protruding toward the inner side in the radial direction.

The first core 2a-1, the intermediate core 2c1, the second core 2a-2, the intermediate core 2c3, the fourth core 2b-2, the intermediate core 2c2, and the third core 2b-1 are stacked and integrated by caulking, adhesion, or a combination of them.

As shown in the developed views of the cores in FIG. 2, the first teeth 3a1 and the second teeth 3a2 formed in staggered arrangement in the circumferential direction of the first core 2a-1 and the second core 2a-2 in the first torque detection part 7a, and the third teeth 3b1 and the fourth teeth 3b2 formed in staggered arrangement in the circumferential direction of the third core 2b-1 and the fourth core 2b-2 in the second torque detection part 7b are stacked in mirror symmetry with respect to the symmetry plane M. Note that teeth around which coils are not wound may exist in the respective cores. Accordingly, a large number of magnetic paths effective for torque detection having inclinations of ±45 degrees can be formed to thereby improve detection sensitivity.

Embodiments of excitation patterns through the first energizing circuit 6a1, the second energizing circuit 6a2, the third energizing circuit 6b1, and the fourth energizing circuit 6b2 will be explained below.

### Embodiment 1

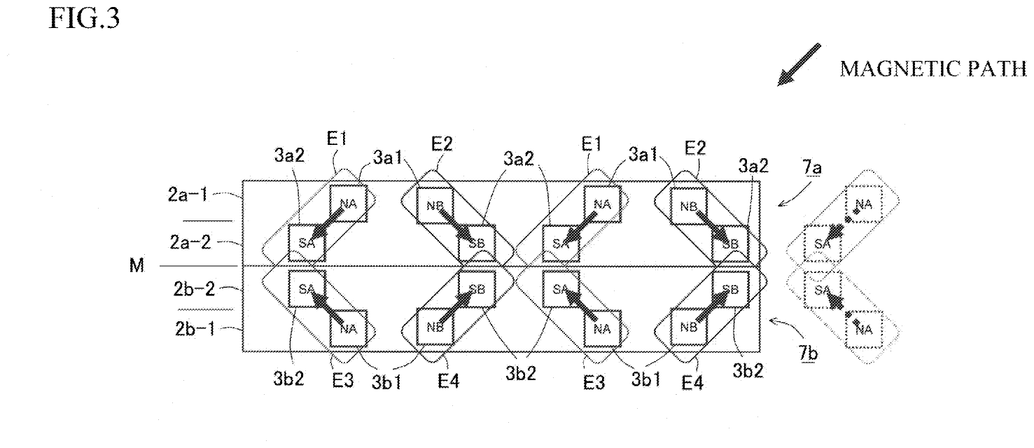

FIG. 3 shows an example of magnetic paths formed by supplying power to the above first and second energizing circuits 6a1, 6a2, and third and fourth energizing circuits 6b1, 6b2. NA in the drawing denotes teeth excited to N-pole by coils A, and SA denotes teeth excited to S-pole by the coils A. Similarly, NB in the drawing denotes teeth excited to N-pole by coils B and SB denotes teeth excited to S-pole by the coils B. More precisely, tip portions of teeth facing an object to be detected S are excited to N-pole or S-pole. Whether being excited to N-pole or excited to S-pole can be determined by inverting directions in which the coils A and coils B (the first coils 5a1 and the second coils 5a2, the third coils 5b1 and the fourth coils 5b2) are wound. Long frames E1, E2 surrounding NA, SA and NB, SB represent inclinations of magnetic paths with respect to the axial center direction (a vertical direction of the drawing) in the magnetic paths formed between the first teeth 3a1 and the second teeth 3a2. Similarly, long frames E3, E4 surrounding NA, SA and NB, SB represent inclinations of magnetic paths with respect to the axial center direction (the vertical direction of the drawing) in the magnetic paths formed between the third teeth 3b1 and the fourth teeth 3b2.

As shown in FIG. 3, the first teeth 3a1 adjacent to each other in the circumferential direction of the first core 2a-1 are excited to N-pole (or S-pole), and the second teeth 3a2 adjacent to each other in the circumferential direction of the second core 2a-2 are excited to S-pole (or N-pole).

The third teeth 3b1 adjacent in the circumferential direction of the third core 2b-1 are excited to N-pole (or S-pole) and the fourth teeth 3b2 adjacent to each other in the circumferential direction of the fourth core 2b-2 are excited to S-pole (or N-pole).

As described above, when the teeth formed in the circumferential direction of respective cores are excited so as to be the same polarity, a plurality of magnetic paths with ±45 degrees which are effective for torque detection can be formed without forming magnetic paths crossing the symmetry plane M between the first toque detection part 7a and the second torque detection part 7b; therefore, detection sensitivity can be improved.

### Embodiment 2

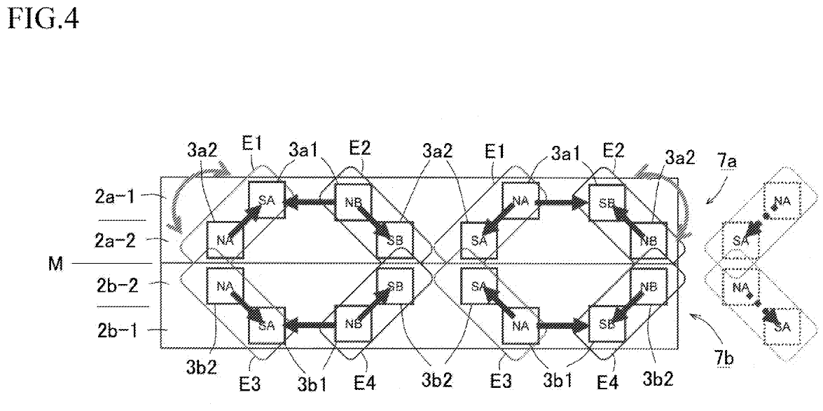

In FIG. 4, the first teeth 3a1 adjacent to each other in the circumferential direction of the first core 2a-1, the second teeth 3a2 adjacent to each other in the circumferential direction of the second core 2a-2, the third teeth 3b1 adjacent to each other in the circumferential direction of the third core 2b-1, and the fourth teeth 3b2 adjacent in the circumferential direction of the fourth core 2b-2 may be excited to different polarities.

In this case, the second teeth 3a2 and the fourth teeth 3b2 as well as the first teeth 3a1 and the third teeth 3b1 placed at symmetrical positions through the symmetry plane M have the same magnetic poles; therefore, magnetic paths crossing the symmetry plane M between the first torque detection part 7a and the second torque detection part 7b are not formed. However, magnetic paths (NB→SA), (NA→SB) are formed between teeth adjacent in the circumferential direction in the first teeth 3a1 and the third teeth 3b1. However, these magnetic paths have magnetic path components having little effect on torque detection. Accordingly, these magnetic paths have little effect on detection sensitivity, though the efficiency is reduced.

### Embodiment 3

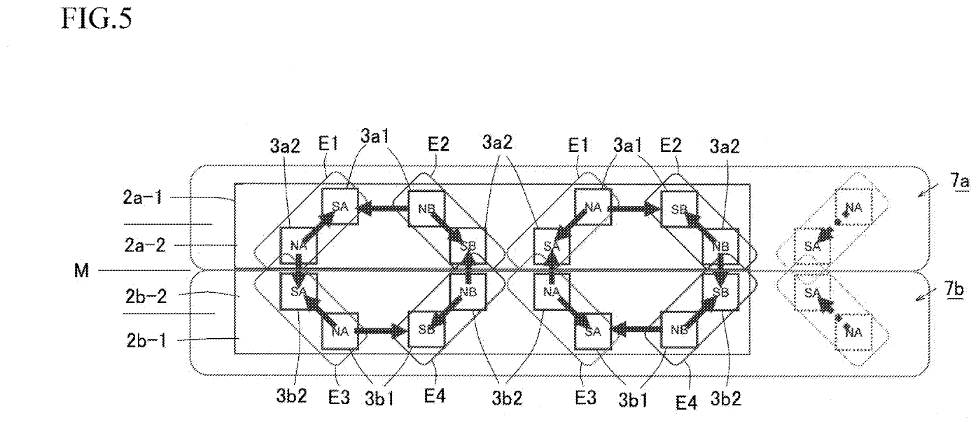

As shown in FIG. 5, the first teeth 3a1 of the first core 2a-1 are excited to S-pole (or N-pole) and the third teeth 3b1 of the third core 2b-1 are excited to N-pole (or S-pole) which are placed at symmetrical positions through the symmetry plane M between the first torque detection part 7a and the second torque detection part 7b. The second teeth 3a2 of the second core 2a-2 are excited to S-pole (or N-pole) and the fourth teeth 3b2 of the fourth core 2b-2 are excited to N-pole (or S-pole) which are placed at symmetrical positions through the symmetry plane M.

In this case, magnetic paths (NB→SA), (NA→SB) are formed between teeth adjacent in the circumferential direction in the first teeth 3a1 and the third teeth 3b1, and further, magnetic paths (NA→SA), (NB→SB) are formed in the axial center direction (a vertical direction in FIG. 5) of the object to be detected between the second teeth 3a2 and the fourth teeth 3b2 so as to cross the symmetry plane M between the first torque detection part 7a and the second torque detection part 7b. However, these magnetic paths have magnetic path components having little effect on torque detection. Accordingly, these magnetic paths have little effect on detection sensitivity, though the efficiency is reduced.

### Embodiment 4

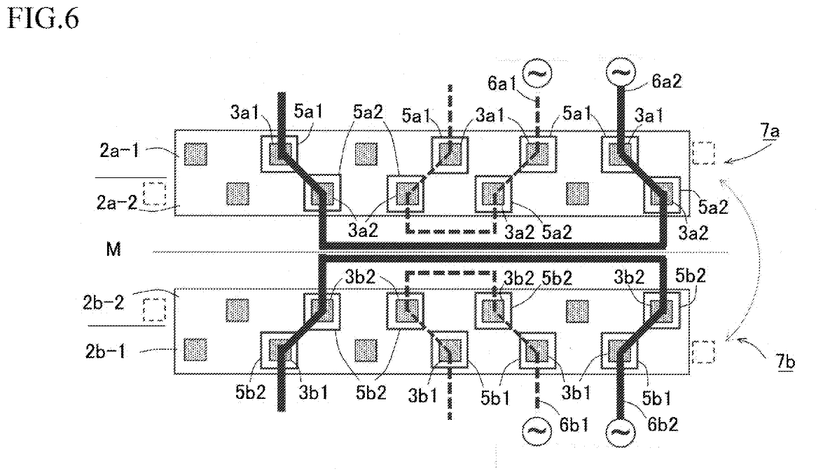

Next, other configurations of the torque detection sensor 1 will be explained with reference to FIG. 6 to FIG. 8.

In a development view of cores shown in FIG. 6, the configuration is the same as that of FIG. 2 in a point that the first energizing circuit 6a1 and the third energizing circuit 6b1 are arranged in mirror symmetry with respect to the symmetry plane M orthogonal to the axial center direction of the object to be detected, and the second energizing circuit 6a2 and the fourth energizing circuit 6b2 are stacked in mirror symmetry. The configuration is the same as that of FIG. 2 also in a point that the first teeth 3a1 and the second teeth 3a2 formed in staggered arrangement in the circumferential direction of the first core 2a-1 and the second core 2a-2 of the first torque detection part 7a, and the third teeth 3b1 and the fourth teeth 3b2 formed in staggered arrangement in the circumferential direction of the third core 2b-1 and the fourth core 2b-2 of the second torque detection part 7b are stacked in mirror symmetry with respect to the symmetry plane M.

However, the configuration differs in a point that the first energizing circuit 6a1 (a broken line part) and the second energizing circuit 6a2 (a solid line part) included in the first torque detection part 7a are not arranged so as to cross each other as shown in FIG. 6, and in a point that the third energizing circuit 6b1 (a broken line part) and the fourth energizing circuit 6b2 (a solid line part) included in the second torque detection part 7b are not arranged so as to cross each other.

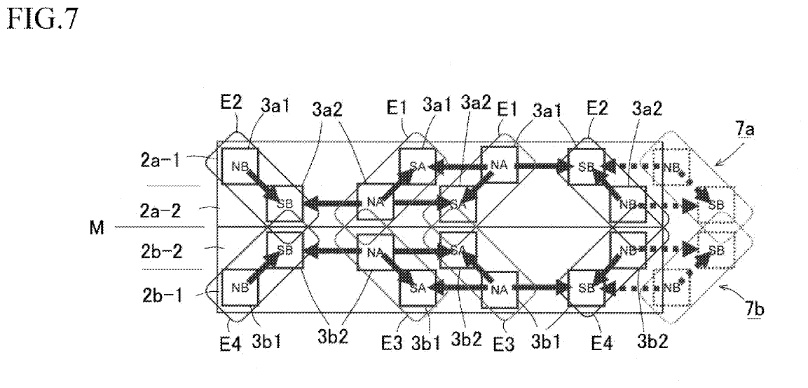

FIG. 7 shows an example of magnetic paths formed by supplying power to the first and the second energizing circuits 6a1, 6a2 and the third and the fourth energizing circuits 6b1, 6b2 shown in FIG. 6. As shown in FIG. 7, the first teeth 3a1 adjacent to each other in the circumferential direction of the first core 2a-1 are alternately excited to N-pole or S-pole, and the second teeth 3a2 adjacent to each other in the circumferential direction of the second core 2a-2 are also excited to S-pole or N-pole.

The third teeth 3b1 adjacent to each other in the circumferential direction of the third core 2b-1 are alternately excited to N-pole or S-pole, and the fourth teeth 3b2 adjacent to each other in the circumferential direction of the fourth core 2b-2 are alternately excited to S-pole or N-pole.

In this case, magnetic paths crossing the symmetry plane M between the first torque detection part 7a and the second torque detection part 7b are not formed; however, magnetic paths (NA→SA), (NB→SB), (NA→SB) are formed between teeth adjacent to the first teeth 3a1 and the second teeth 3a2 in the circumferential direction in the first torque detection part 7a. Similar magnetic paths are formed also between teeth adjacent to the third teeth 3b1 and the fourth teeth 3b2 in the circumferential direction in the second torque detection part 7b.

However, these magnetic paths have magnetic path components having little effect on torque detection. Accordingly, these magnetic paths have little effect on detection sensitivity, though the efficiency is reduced.

### Embodiment 5

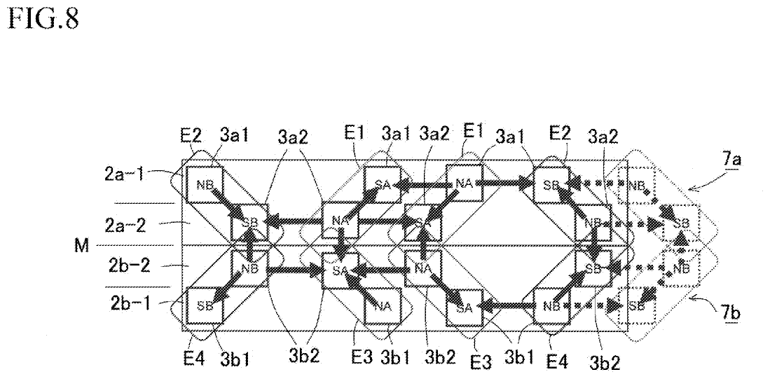

FIG. 8 shows an example of magnetic paths formed by supplying power to the first and the second energizing circuits 6a1, 6a2, and the third and the fourth energizing circuits 6b1, 6b2 shown in FIG. 6. As shown in FIG. 8, the first teeth 3a1 adjacent to each other in the circumferential direction of the first core 2a-1 are alternately excited to N-pole or S-pole, and the second teeth 3a2 adjacent to each other in the circumferential direction of the second core 2a-2 are also excited to S-pole or N-pole alternately.

The third teeth 3b1 adjacent to each other in the circumferential direction of the third core 2b-1 are alternately excited to N-pole or S-pole, and the fourth teeth 3b2 adjacent to each other in the circumferential direction of the fourth core 2b-2 are alternately excited to S-pole or N-pole.

In this case, magnetic paths (NA→SA), (NA→SB), (NB→SB), (NB→SA) are respectively formed between teeth adjacent to the first teeth 3a1 to the fourth teeth 3b2 in the circumferential direction, and further, magnetic paths are formed so as to cross the symmetry plane M between the first torque detection part 7a and the second torque detection part 7b. That is, magnetic paths (NA→SA), (NB→SB) are formed between the second teeth 3 a2 in the first torque detection part 7a and the fourth teeth 3b2 in the second torque detection part 7b arranged at opposite positions so as to cross the symmetry plane M.

However, these magnetic paths have magnetic path components having little effect on torque detection. Accordingly, these magnetic paths have little effect on detection sensitivity, though the efficiency is reduced.

### Embodiment 6

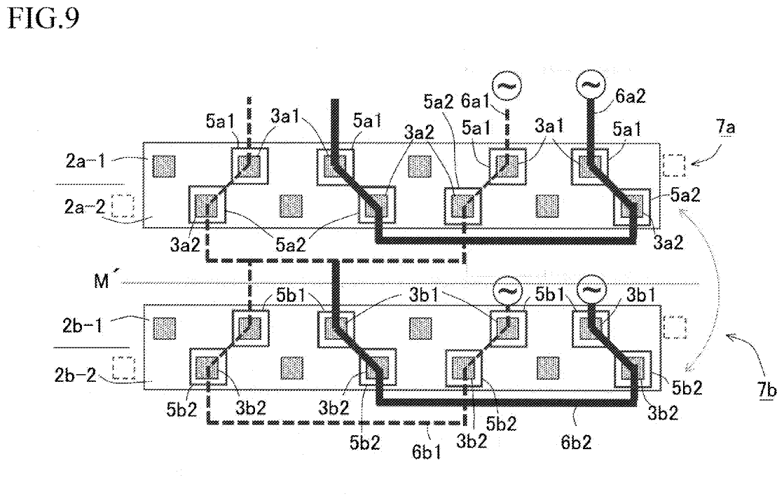

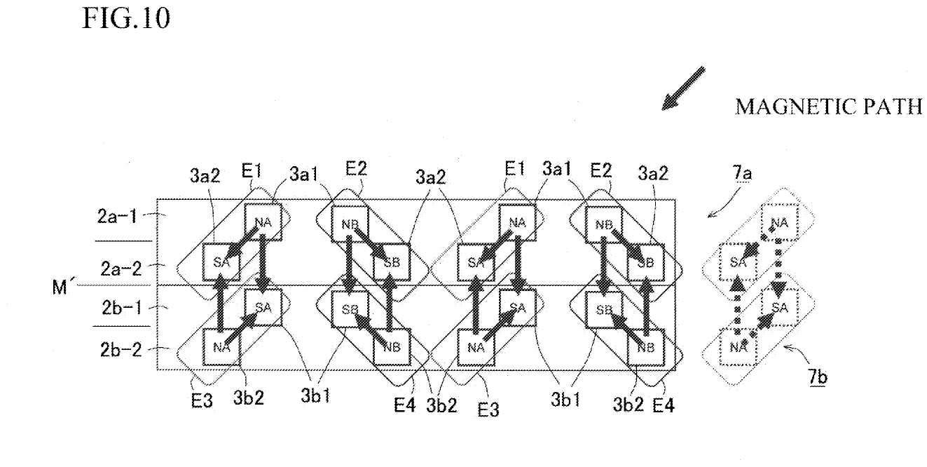

Next, other configurations of the torque detection sensor 1 will be explained with reference to FIG. 9 and FIG. 10. Schematic configurations of the first torque detection part 7a and the second torque detection part 7b included in the torque detection sensor 1 are the same as those of FIG. 1.

In FIG. 9, the configuration is the same as that of Embodiment 1 in a point that the plural first teeth 3a1 and second teeth 3a2 are provided to protrude in staggered arrangement in the circumferential direction in the annular first core 2a-1 and second core 2a-2 in the first torque detection part 7a. The configuration is also the same as that of Embodiment 1 in a point that the first energizing circuit 6a1 (a broken line part) in which the first coils 5a1 and the second coils 5a2 respectively wound around the first teeth 3a1 and the second teeth 3 a2 having the inclination of +45 degrees with respect to the axial center direction are connected in series and the second energizing circuit 6a2 (a solid line part) in which the first coils 5a1 and the second coils 5a2 respectively wound around the first teeth 3a1 and the second teeth 3a2 having the inclination of −45 degrees with respect to the axial center direction are connected in series are included.

The configuration is the same as that of Embodiment 1 in a point that the plural third teeth 3b1 and fourth teeth 3b2 are provided to protrude in staggered arrangement in the circumferential direction in the annular third core 2b-1 and fourth core 2b-2 in the second torque detection part 7b. The configuration is also the same as that of Embodiment 1 in a point that the third energizing circuit 6b1 (a broken line part) in which the third coils 5b1 and the fourth coils 5b2 respectively wound around the third teeth 3b1 and the fourth teeth 3b2 having the inclination of +45 degrees with respect to the axial center direction are connected in series and the fourth energizing circuit 6b2 (a solid line part) in which the third coils 5b1 and the fourth coils 5b2 respectively wound around the third teeth 3b1 and the fourth teeth 3b2 having the inclination of −45 degrees with respect to the axial center direction are connected in series are included.

However, the first torque detection part 7a and the second torque detection part 7b are stacked so that layouts are the same between the first energizing circuit 6a1 and the third energizing circuit 6b1 (broken line parts), and layouts are the same between the second energizing circuit 6a2 and the fourth energizing circuit 6b2 (solid line parts) in the axial center direction (a vertical direction of FIG. 9) and the circumferential direction (a right and left direction of FIG. 9) of the object to be detected. The first energizing circuit 6a1 and the second energizing circuit 6a2 are arranged so as to cross each other and the third energizing circuit 6b1 and the fourth energizing circuit 6b2 are arranged so as to cross each other.

In this case, the layouts are the same between the first energizing circuit 6a1 and the third energizing circuit 6b1, and the layouts are the same between the second energizing circuit 6a2 and the fourth energizing circuit 6b2 in the axial center direction and the circumferential direction of the object to be detected; therefore, a large number of plural magnetic paths having inclinations of ±45 degrees can be respectively formed along the axial direction, for example, only by preparing a plurality of the first torque detection parts 7a and the second torque detection parts 7b and arranging them so as to be stacked in the axial center direction of the object to be detected. Accordingly, compressive stress and tensile stress generated over the entire periphery of the object to be detected can be delicately detected by increasing magnetic paths effective for torque detection.

The teeth are stacked so that magnetic poles of the first teeth 3a1 and the second teeth 3a2 excited by the first energizing circuit 6a1 and the second energizing circuit 6a2 are asymmetrically arranged with respect to magnetic poles of the third teeth 3b1 and the fourth teeth 3b2 excited by the third energizing circuit 6b1 and the fourth energizing circuit 6b2. In this case, the second core 2a-2 and the third core 2b-1 are stacked through the intermediate core 2c3; therefore, a central part of the intermediate core 2c3 in the stacked direction is a lamination plane M′.

Accordingly, a torque detection sensor with high detection sensitivity can be manufactured only by forming a plurality of the first torque detection parts 7a or the second torque detection parts 7b to be stacked so as to align layouts of the energizing circuits.

FIG. 10 shows an example of magnetic paths formed by supplying power to the first and the second energizing circuits 6a1, 6a2, and the third and the fourth energizing circuits 6b1, 6b2 shown in FIG. 9. As shown in FIG. 10, the first teeth 3a1 adjacent to each other in the circumferential direction of the first core 2a-1 are excited to N-pole (or S-pole), and the second teeth 3a2 adjacent to each other in the circumferential direction of the second core 2a-2 are excited to S-pole (or N-pole).

The third teeth 3b1 adjacent to each other in the circumferential direction of the third core 2b-1 are excited to S-pole (or N-pole), and the fourth teeth 3b2 adjacent to each other in the circumferential direction of the fourth core 2b-2 are excited to N-pole (or S-pole).

In this case, magnetic paths (NA→SA), (NB→SB) are respectively formed between the first teeth 3a1 and the third teeth 3b1 and between the second teeth 3a2 and the fourth teeth 3b2 which face in the axial center direction of the object to be detected so as to cross the lamination plane M′.

However, these magnetic paths have magnetic path components having little effect on torque detection. Accordingly, these magnetic paths have little effect on detection sensitivity, though the efficiency is reduced.

### Embodiment 7

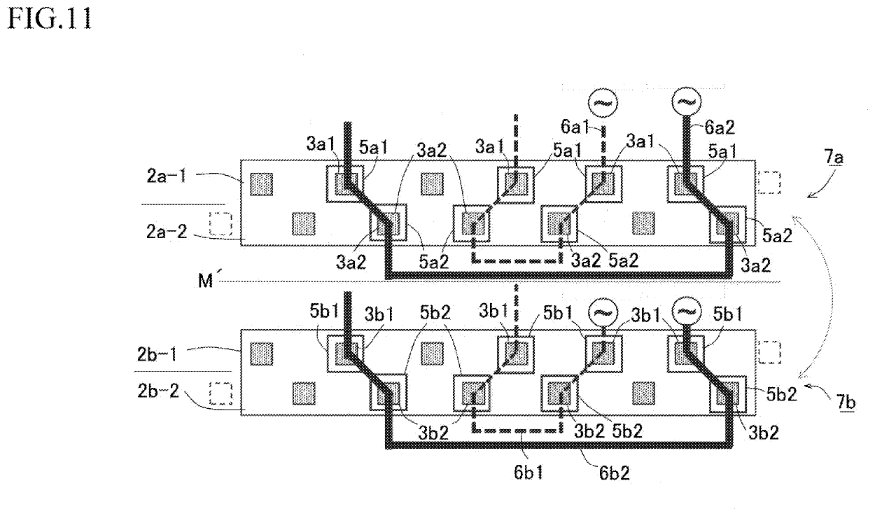

Next, another configuration of the torque detection sensor 1 shown in FIG. 9 will be explained with reference to FIG. 11. The configuration is the same as that of FIG. 9 in a point that the first torque detection part 7a and the second torque detection part 7b are stacked so that layouts are the same between the first energizing circuit 6a1 and the third energizing circuit 6b1 (broken line parts), and layouts are the same between the second energizing circuit 6a2 and the fourth energizing circuit 6b2 (solid line parts) in the axial center direction (a vertical direction of FIG. 11) and the circumferential direction (a right and left direction of FIG. 11) of the object to be detected. However, the configuration differs from that of FIG. 9 in a point that the first energizing circuit 6a1 and the second energizing circuit 6a2 are not arranged so as to cross, and the third energizing circuit 6b1 and the fourth energizing circuit 6b2 are not arranged so as to cross either.

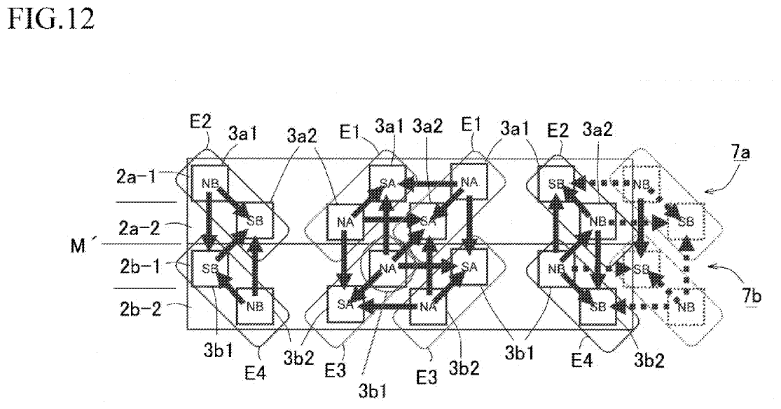

FIG. 12 shows an example of magnetic paths formed by supplying power to the first and the second energizing circuits 6a1, 6a2 and the third and the fourth energizing circuits 6b1, 6b2 shown in FIG. 11. As shown in FIG. 12, the first teeth 3a1 adjacent to each other in the circumferential direction of the first core 2a-1 are alternately excited to N-pole or S-pole, and the second teeth 3a2 adjacent to each other in the circumferential direction of the second core 2a-2 are also alternately excited to S-pole or N-pole.

The third teeth 3b1 adjacent to each other in the circumferential direction of the third core 2b-1 are alternately excited to S-pole or N-pole, and the fourth teeth 3b2 adjacent to each other in the circumferential direction of the fourth core 2b-2 are also alternately excited to N-pole or S-pole.

In this case, when attention is focused on a third tooth 3b1 (magnetic pole NA) shown by a circle in FIG. 12, a magnetic path (NA→SA) with respect to a second tooth 3a2 (magnetic pole SA) and a magnetic path (NA→SA) with respect to a fourth tooth 3b2 (magnetic pole SA) cancel out each other; however, a plurality of magnetic paths with ±45 degrees are formed in the first torque detection part 7a and the second torque detection part 7b. Moreover, a magnetic path (NA→SA) formed between a first tooth 3a1 and the third tooth 3b1 so as to cross the lamination plane M′, a magnetic path (NA→SA) formed between the second tooth 3a2 and the fourth teeth 3b2 so as to cross the lamination plane M′, and magnetic paths formed between teeth adjacent to each other in the circumferential direction in the first teeth 3a1 to the fourth teeth 3b2 have magnetic path components having little effect on torque detection. Accordingly, these magnetic paths have little effect on detection sensitivity, though the efficiency is reduced.

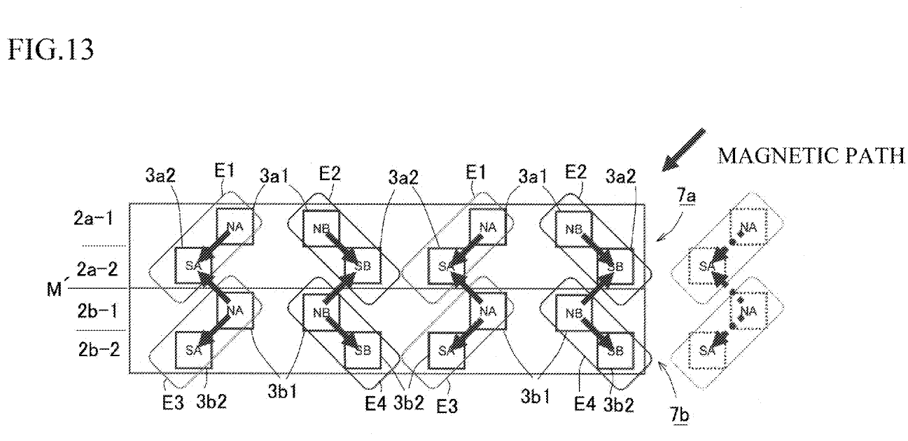

Here, a comparative example of Embodiment 6 shown in FIG. 9 will be explained with reference to FIG. 13. FIG. 13 shows an example of magnetic paths formed by supplying power to the first and the second energizing circuits 6a1, 6a2, and the third and the fourth energizing circuits 6b1, 6b2 shown in FIG. 9.

When attention is focused on the third teeth 3b1 (magnetic poles NA, NB) in the second torque detection part 7b, magnetic paths (NA→SA), (NB→SB) having the inclination of ±45 degrees are formed with respect to the second teeth 3a2, and magnetic paths (NA→SA), (NB→SB) having the inclination of ±45 degrees are formed with respect to the fourth teeth 3b2 (magnetic poles SA, SB). As these magnetic paths cancel out each other, detection sensitivity is reduced. Accordingly, such excitation is not desirable.

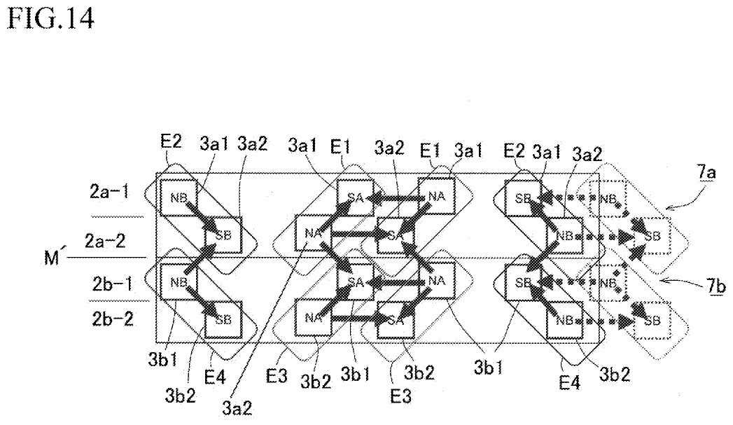

Here, a comparative example of Embodiment 7 shown in FIG. 11 will be explained with reference to FIG. 14. FIG. 14 shows an example of magnetic paths formed by supplying power to the first and the second energizing circuits 6a1, 6a2, and the third and the fourth energizing circuits 6b1, 6b2 shown in FIG. 11.

When attention is focused on a second tooth 3a2 (magnetic pole NA) in the first torque detection part 7a, a magnetic path (NA→SA) having the inclination of +45 degrees is formed with respect to a first tooth 3a1, and a magnetic path (NA→SA) having the inclination of −45 degrees is formed with respect to a third tooth 3b1. As these magnetic paths cancel out each other, detection sensitivity is reduced. Accordingly, such excitation is not desirable.

Next, other examples of the torque detection sensor 1 will be shown. All sensors according to the above embodiments are inner-type sensors in which a solid shaft material is assumed to be used as the object to be detected. That is, the teeth are provided to protrude in the core on the inner side in the radial direction. However, the type of the sensor is not limited to this, and an outer-type sensor in which torque variation can be detected even when the object to be detected is a cylindrical material (hollow shaft) may be adopted. That is, teeth are provided to protrude in the core on an outer side in the radial direction.

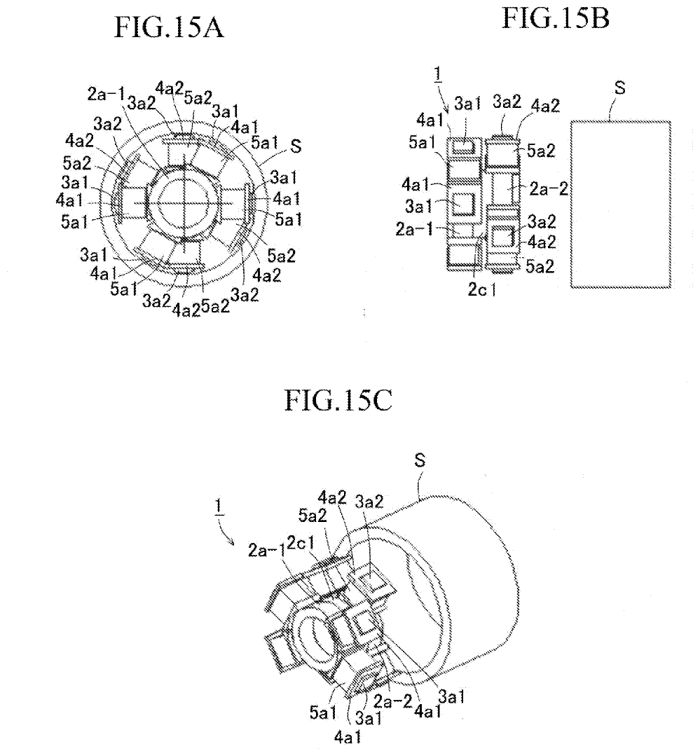

FIGS. 15A to 15C are a front view of the torque detection sensor 1 according to another embodiment, a side view and a perspective view showing a state before assembly. A configuration of the first torque detection part 7a is shown in FIGS. 15A to 15C. The annular first core 2a-1, intermediate core 2c1, and second core 2a-2 are integrally stacked. In the first core 2a-1, four first teeth 3a1 in total are provided to protrude in the annular core back portion 2a1 with a predetermined phase difference in the circumferential direction and at opposite positions toward the outer side in the radial direction. In the second core 2a-2, four second teeth 3a2 in total are provided to protrude in the annular core back portion 2a2 with a predetermined phase difference in the circumferential direction and at opposite positions toward the outer side in the radial direction. The first coils 5a1 are wound around the first teeth 3a1 through the first insulators 4a1, and the second coils 5a2 are wound around the second teeth 3a2 through the second insulators 4a2. The first core 2a-1 and the second core 2a-2 are stacked through the intermediate core 2c1, and the first teeth 3a1 and the second teeth 3a2 are stacked with a phase difference of 45 degrees in the circumferential direction to make four pairs. The configurations of the first energizing circuit 6a1 and the second energizing circuit 6a2 including the first coils 5a1 and the second coils 5a2, which are connected in series, are the same as those of FIG. 2. Note that the third core 2b-1 and the fourth core 2b-2 are stacked through the intermediate core 2c2, though not shown. In the third core 2b-1, the third teeth 3b1 are provided to protrude in the annular core back portion 2b1 toward the outer side in the radial direction. In the fourth core 2b-2, the fourth teeth 3b2 are provided to protrude in the annular core back portion 2b2 toward the outer side in the radial direction. The third teeth 3b1 and the fourth teeth 3b2 are stacked with the phase difference of 45 degrees in the circumferential direction, which makes four pairs. The configurations of the third energizing circuit 6b1 and the fourth energizing circuit 6b2 including the third coils 5b1 and the fourth coils 5b2, which are connected in series, are the same as those of FIG. 2. The cores are stacked so that the annular intermediate core 2c3 is interposed between the second core 2a-2 and the fourth core 2b-2.

The above torque detection sensor 1 is concentrically inserted into a hollow hole of the object to be detected S (hollow shaft), and the first teeth 3a1, the second teeth 3a2, the third teeth 3b1, and the fourth teeth 3b2 are assembled so as to face an inner peripheral surface of the object to be detected S. Accordingly, a plurality of magnetic paths including the object to be detected are formed among the teeth provided in staggered arrangement, and torque variation can be detected from magnetic path components of ±45 degrees.

As described above, the sensor can detect torque variation of not only the solid shaft but also the hollow shaft as the object to be detected S, which improves versatility.

As explained above, the plural magnetic paths effective for torque detection are respectively formed among the teeth having inclinations of ±45 degrees in the first torque detection part 7a and the second torque detection part 7b; therefore, compressive stress and tensile stress generated over the entire periphery of the object to be detected can be delicately detected by increasing magnetic paths effective for torque detection.

What is claimed is:

1. A torque detection sensor measuring variation of magnetic permeability by variation of coil impedance in magnetic circuits formed between a core and an object to be detected by energizing coils wound around teeth provided to protrude from the annular core provided around the object to be detected at plural places, the sensor comprising:
a first torque detection part in which a plurality of first teeth and second teeth are provided to protrude in staggered arrangement in annular first core and second core in a circumferential direction, having a first energizing circuit in which first coils wound around the first teeth and second coils wound around the second teeth arranged with an inclination of +45 degrees with respect to an axial center direction of the object to be detected are connected in series, and a second energizing circuit in which the first coils wound around the first teeth and the second coils wound around the second teeth arranged with an inclination of −45 degrees with respect to the axial center direction of the object to be detected are connected in series; and
a second torque detection part in which a plurality of third teeth and fourth teeth are provided to protrude in staggered arrangement in annular third core and fourth core in a circumferential direction, having a third energizing circuit in which third coils wound around the third teeth and fourth coils wound around the fourth teeth arranged with the inclination of +45 degrees with respect to the axial center direction of the object to be detected are connected in series, and a fourth energizing circuit in which the third coils wound around the third teeth and the fourth coils wound around the fourth teeth arranged with the inclination of −45 degrees with respect to the axial center direction of the object to be detected are connected in series,
wherein the first torque detection part and the second torque detection part are stacked so that the first energizing circuit and the third energizing circuit are arranged in mirror symmetry as well as the second energizing circuit and the fourth energizing circuit are arranged in mirror symmetry with respect to a symmetry plane orthogonal to the axial center direction of the object to be detected.

2. The torque detection sensor according to claim 1,
wherein arrangement of magnetic poles of the first teeth and the second teeth excited by the first energizing circuit and the second energizing circuit and arrangement of magnetic poles of the third teeth and the fourth teeth excited by the third energizing circuit and the fourth energizing circuit are in mirror symmetry through the symmetry plane.

3. The torque detection sensor according to claim 1,
wherein the first teeth adjacent to each other in the circumferential direction of the first core, the second teeth adjacent to each other in the circumferential direction of the second core, the third teeth adjacent to each other in the circumferential direction of the third core, and the fourth teeth adjacent to each other in the circumferential direction of the fourth core are excited to the same polarity.

4. The torque detection sensor according to claim 1,
wherein the first teeth of the first core and the third teeth of the third core arranged at symmetrical positions through the symmetry plane as well as the second teeth of the second core and the fourth teeth of the fourth core arranged at symmetrical positions through the symmetry plane in the first torque detection part and the second torque detection part are excited to the same polarity.

5. The torque detection sensor according to claim 1,
wherein the first teeth of the first core and the third teeth of the third core arranged at symmetrical positions through the symmetry plane as well as the second teeth of the second core and the fourth teeth of the fourth core arranged at symmetrical positions through the symmetry plane in the first torque detection part and the second torque detection part are excited to different polarities.

6. A torque detection sensor measuring variation of magnetic permeability by variation of coil impedance in magnetic circuits formed between a core and an object to be detected by energizing coils wound around teeth provided to protrude from the annular core provided around the object to be detected at plural places, the sensor comprising:
a first torque detection part in which a plurality of first teeth and second teeth are provided to protrude in staggered arrangement in annular first core and second core in a circumferential direction, having a first energizing circuit in which first coils wound around the first teeth and second coils wound around the second teeth arranged with an inclination of +45 degrees with respect to an axial center direction of the object to be detected are connected in series, and a second energizing circuit in which the first coils wound around the first teeth and the second coils wound around the second teeth arranged with an inclination of −45 degrees with respect to the axial center direction of the object to be detected are connected in series; and
a second torque detection part in which a plurality of third teeth and fourth teeth are provided to protrude in staggered arrangement in annular third core and fourth core in a circumferential direction, having a third energizing circuit in which third coils wound around the third teeth and fourth coils wound around the fourth teeth arranged with the inclination of +45 degrees with respect to the axial center direction of the object to be detected are connected in series, and a fourth energizing circuit in which the third coils wound around the third teeth and the fourth coils wound around the fourth teeth arranged with the inclination of −45 degrees with respect to the axial center direction of the object to be detected are connected in series,
wherein the first torque detection part and the second torque detection part are stacked so that layouts are the same between the first energizing circuit and the third energizing circuit, and layouts are the same between the second energizing circuit and the fourth energizing circuit in the axial center direction and the circumferential direction of the object to be detected.

7. The torque detection sensor according to claim 6,
wherein magnetic poles of the first teeth and the second teeth excited by the first energizing circuit and the second energizing circuit are asymmetrically arranged with respect to magnetic poles of the third teeth and the fourth teeth excited by the third energizing circuit and the fourth energizing circuit.

8. The torque detection sensor according to claim 6,
wherein the first teeth adjacent to each other in the circumferential direction of the first core, the second teeth adjacent to each other in the circumferential direction of the second core, the third teeth adjacent to each other in the circumferential direction of the third core, and the fourth teeth adjacent to each other in the circumferential direction of the fourth core are excited to the same polarity.

9. The torque detection sensor according to claim 6,
wherein the first teeth adjacent to each other in the circumferential direction of the first core, the second teeth adjacent to each other in the circumferential direction of the second core, the third teeth adjacent to each other in the circumferential direction of the third core, and the fourth teeth adjacent to each other in the circumferential direction of the fourth core are excited to different polarities.

10. The torque detection sensor according to claim 1,
wherein the sensor is a self-excitation sensor measuring variation of magnetic permeability by variation of coil impedance in magnetic circuits formed between the core and the object to be detected by supplying power to the first energizing circuit, the second energizing circuit, the third energizing circuit, and the fourth energizing circuit.

11. The torque detection sensor according to claim 6,
wherein the sensor is a self-excitation sensor measuring variation of magnetic permeability by variation of coil impedance in magnetic circuits formed between the core and the object to be detected by supplying power to the first energizing circuit, the second energizing circuit, the third energizing circuit, and the fourth energizing circuit.
